(19) United States
(12) Patent Application Publication
(10) Pub. No.: US 2024/0413025 A1
(43) Pub. Date: Dec. 12, 2024

(54) METHODS FOR PRODUCING A SEAL FOR A SEMICONDUCTOR MODULE, AND A HOUSING FOR A SEMICONDUCTOR MODULE

(71) Applicant: Infineon Technologies AG, Neubiberg (DE)

(72) Inventors: Georg Troska, Frondenberg (DE); Anita Herzer, Kaiserslautern (DE); Fabian Jäger, Bestwig (DE); Markus Wiesemann, Bielefeld (DE)

(21) Appl. No.: 18/732,716

(22) Filed: Jun. 4, 2024

(30) Foreign Application Priority Data
Jun. 6, 2023 (EP) 23177665.9

(51) Int. Cl. H01L 23/10; H01L 21/48; H01L 21/56; H01L 23/053; H01L 23/31; H01L 23/373

(52) U.S. Cl. CPC H01L 23/10; H01L 21/4807; H01L 21/565; H01L 23/053; H01L 23/3121; H01L 23/3735

(57) ABSTRACT

A method includes applying a first material to a first surface, the first material including a matrix material and an adhesion promoter. The matrix material is configured to cure when heated to a defined temperature for a defined period of time. The adhesion promoter is configured to be activated when heated to a temperature that is higher than the defined temperature and/or for a period of time that is longer than the defined period of time. The method further includes heating the first material to the defined temperature for the defined period of time such that the matrix material cures and the adhesion promoter remains inactive, thereby forming a pre-seal.

### TECHNICAL FIELD

The instant disclosure relates to a method for producing a seal for a semiconductor module, and to a housing for a semiconductor module.

### BACKGROUND

Power semiconductor module arrangements often include at least one semiconductor substrate arranged in a housing. A semiconductor arrangement including a plurality of controllable semiconductor elements (e.g., two IGBTs in a half-bridge configuration) is arranged on each of the at least one substrates. Each substrate usually comprises a substrate layer (e.g., a ceramic layer), a first metallization layer deposited on a first side of the substrate layer and a second metallization layer deposited on a second side of the substrate layer. The controllable semiconductor elements are mounted, for example, on the first metallization layer. The second metallization layer may optionally be attached to a base plate. The controllable semiconductor devices are usually mounted onto the semiconductor substrate by soldering or sintering techniques.

The components of the semiconductor module arrangement are usually protected from mechanical damage or other environmental impacts by means of a housing. The housing needs to be securely mounted either to the substrate or to the base plate, for example. A seal may be arranged between the housing and the substrate or base plate in order to prevent particles or gases from entering the inside of the housing.

There is a need for a semiconductor module arrangement that offers protection for the semiconductor components arranged therein such that the overall lifetime of the power semiconductor module arrangement is increased.

### SUMMARY

A method includes applying a first material to a first surface, the first material including a matrix material and an adhesion promoter, wherein the matrix material is configured to cure when heated to a defined temperature for a defined period of time, and wherein the adhesion promoter is configured to be activated when heated to a temperature that is higher than the defined temperature and/or for a period of time that is longer than the defined period of time, and heating the first material to the defined temperature for the defined period of time such that the matrix material cures and the adhesion promoter remains inactive, thereby forming a pre-seal.

A housing for a power semiconductor module arrangement includes sidewalls and a cover, and a pre-seal arranged on a lower surface of the sidewalls, wherein the pre-seal comprises a cured matrix material and an adhesion promoter, wherein the adhesion promoter is configured to be activated at or above a second temperature.

The invention may be better understood with reference to the following drawings and the description. The components in the figures are not necessarily to scale, emphasis instead being placed upon illustrating the principles of the invention. Moreover, in the figures, like referenced numerals designate corresponding parts throughout the different views.

### BRIEF DESCRIPTION OF THE DRAWINGS

FIG. 1 is a cross-sectional view of a power semiconductor module arrangement.

FIG. 2 is a cross-sectional view of another power semiconductor module arrangement.

FIGS. 3A and 3B illustrate a conventional method for forming a seal and a method for forming a seal according to one example.

FIGS. 4, 5 and 6 schematically illustrate a method for producing a seal for a semiconductor module according to one example.

FIG. 7 is a top view of an exemplary seal for a power semiconductor module arrangement.

FIGS. 8A and 8B illustrate respective cross-sectional views of a housing for a power semiconductor module arrangement with a seal formed thereon.

FIGS. 9A and 9B illustrate respective cross-sectional views of a sidewall of a housing with a seal formed thereon.

### DETAILED DESCRIPTION

In the following detailed description, reference is made to the accompanying drawings. The drawings show specific examples in which the invention may be practiced. It is to be understood that the features and principles described with respect to the various examples may be combined with each other, unless specifically noted otherwise. In the description as well as in the claims, designations of certain elements as “first element”, “second element”, “third element” etc. are not to be understood as enumerative. Instead, such designations serve solely to address different “elements”. That is, e.g., the existence of a “third element” does not require the existence of a “first element” and a “second element”. An electrical line or electrical connection as described herein may be a single electrically conductive element, or include at least two individual electrically conductive elements connected in series and/or parallel. Electrical lines and electrical connections may include metal and/or semiconductor material, and may be permanently electrically conductive (i.e., non-switchable). A semiconductor body as described herein may be made from (doped) semiconductor material and may be a semiconductor chip or be included in a semiconductor chip. A semiconductor body has electrically connecting pads and includes at least one semiconductor element with electrodes.

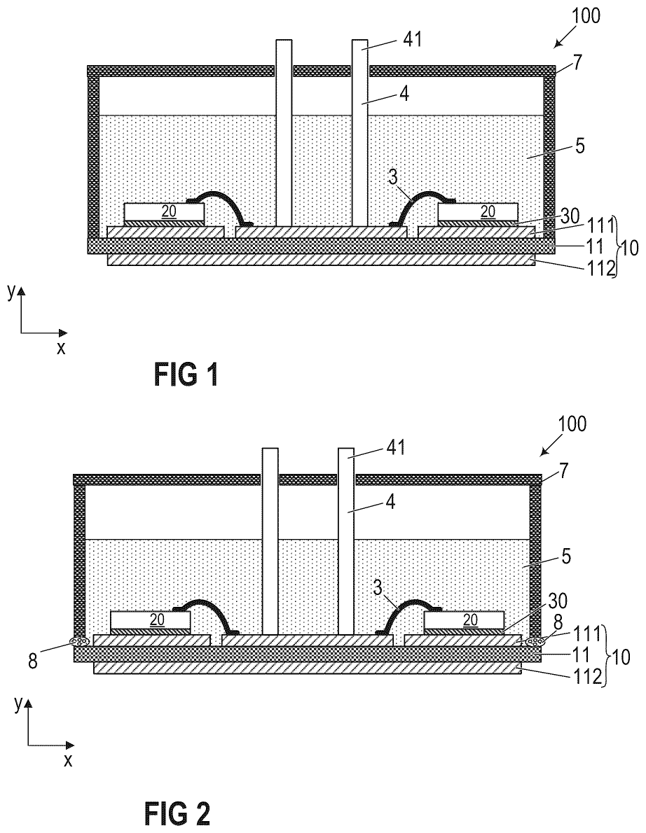

Referring to FIG. 1, a cross-sectional view of a power semiconductor module arrangement 100 is illustrated. The power semiconductor module arrangement 100 includes a housing 7 and a substrate 10. The substrate 10 includes a dielectric insulation layer 11, a (structured) first metallization layer 111 attached to the dielectric insulation layer 11, and a (structured) second metallization layer 112 attached to the dielectric insulation layer 11. The dielectric insulation layer 11 is disposed between the first and second metallization layers 111, 112.

Each of the first and second metallization layers 111, 112 may consist of or include one of the following materials: copper; a copper alloy; aluminum; an aluminum alloy; any other metal or alloy that remains solid during the operation of the power semiconductor module arrangement. The substrate 10 may be a ceramic substrate, that is, a substrate in which the dielectric insulation layer 11 is a ceramic, e.g., a thin ceramic layer. The ceramic may consist of or include one of the following materials: aluminum oxide; aluminum nitride; zirconium oxide; silicon nitride; boron nitride; or any other dielectric ceramic. For example, the dielectric insulation layer 11 may consist of or include one of the following materials: Al₂O₃, AlN, SiC, BeO or Si₃N₄. For instance, the substrate 10 may, e.g., be a Direct Copper Bonding (DCB) substrate, a Direct Aluminum Bonding (DAB) substrate, or an Active Metal Brazing (AMB) substrate. Further, the substrate 10 may be an Insulated Metal Substrate (IMS). An Insulated Metal Substrate generally comprises a dielectric insulation layer 11 comprising (filled) materials such as epoxy resin or polyimide, for example. The material of the dielectric insulation layer 11 may be filled with ceramic particles, for example. Such particles may comprise, e.g., SiO₂, Al₂O₃, AlN, or BN and may have a diameter of between about 1 μm and about 50 μm. The substrate 10 may also be a conventional printed circuit board (PCB) having a non-ceramic dielectric insulation layer 11. For instance, a non-ceramic dielectric insulation layer 11 may consist of or include a cured resin.

The substrate 10 is arranged in a housing 7. In the example illustrated in FIG. 1, the substrate 10 forms a ground surface of the housing 7, while the housing 7 itself solely comprises sidewalls and a cover. This is, however, only an example. It is also possible that the substrate 10 is mounted on a base plate. In some power semiconductor module arrangements 100, more than one substrate 10 is arranged on a single base plate. A base plate may form a ground surface of the housing 7, for example. That is, the sidewalls of the housing 7 may be attached to the base plate, thereby covering the at least one substrate 10.

One or more semiconductor bodies 20 may be arranged on the at least one substrate 10. Each of the semiconductor bodies 20 arranged on the at least one substrate 10 may include a diode, an IGBT (Insulated-Gate Bipolar Transistor), a MOSFET (Metal-Oxide-Semiconductor Field-Effect Transistor), a JFET (Junction Field-Effect Transistor), a HEMT (High-Electron-Mobility Transistor), or any other suitable controllable or non-controllable semiconductor element.

The one or more semiconductor bodies 20 may form a semiconductor arrangement on the substrate 10. In FIG. 1, only two semiconductor bodies 20 are exemplarily illustrated. The second metallization layer 112 of the semiconductor substrate 10 in FIG. 1 is a continuous layer. It is, however, also possible to omit the second metallization layer 112. It is also possible that the second metallization layer 112 is a structured layer. The first metallization layer 111 is a structured layer in the example illustrated in FIG. 1. “Structured layer” in this context means that the first metallization layer 111 is not a continuous layer, but includes recesses between different sections of the layer. Such recesses are schematically illustrated in FIG. 1. The first metallization layer 111 in this example includes three different sections. Different semiconductor bodies 20 may be mounted on the same or to different sections of the first metallization layer 111. Different sections of the first metallization layer may have no electrical connection or may be electrically connected to one or more other sections using, e.g., bonding wires 3. Electrical connections 3 may also include bonding ribbons, connection plates or conductor rails, for example, to name just a few examples. The one or more semiconductor bodies 20 may be electrically and mechanically connected to the substrate 10 by an electrically conductive connection layer 30. Such an electrically conductive connection layer may be a solder layer, a layer of an electrically conductive adhesive, or a layer of a sintered metal powder, e.g., a sintered silver powder, for example.

The power semiconductor module arrangement 100 further includes terminal elements 4. The terminal elements 4 are electrically connected to the first metallization layer 111 and provide an electrical connection between the inside and the outside of the housing 7. The terminal elements 4 may be electrically connected to the first metallization layer 111 with a first end, while a second end 41 of the terminal elements 4 protrudes out of the housing 7. The terminal elements 4 may be electrically contacted from the outside at their second end 41. Such terminal elements 4, however, are only an example. The components inside the housing 7 may be electrically contacted from outside the housing 7 in any other suitable way. For example, terminal elements 4 may be arranged closer or adjacent to the sidewalls of the housing 7. It is also possible that terminal elements 4 protrude vertically or horizontally through the sidewalls of the housing 7. It is even possible that terminal elements 4 protrude through a ground surface of the housing 7.

The semiconductor bodies 20 each may include a chip pad metallization, e.g., a source, drain, anode, cathode or gate metallization. A chip pad metallization generally provides a contact surface for electrically connecting the semiconductor body 20. The chip pad metallization may electrically contact a connection layer 30, a terminal element 4, or an electrical connection 3, for example. A chip pad metallization may consist of or include a metal such as aluminum, copper, gold or silver, for example. The electrical connections 3 and the terminal elements 4 may also consist of or include a metal such as copper, aluminum, gold, or silver, for example.

The power semiconductor module arrangement 100 further includes a casting compound 5. The casting compound 5 may consist of or include a silicone gel, a silicone, polyurethane, epoxy, or polyacrylate based isolation material, or may be a rigid molding compound, for example. The casting compound 5 may at least partly fill the interior of the housing 7, thereby covering the components and electrical connections that are arranged on the substrate 10. The terminal elements 4 may be partly embedded in the casting compound 5. At least their second ends 41, however, are not covered by the casting compound 5 and protrude from the casting compound 5 through the housing 7 to the outside of the housing 7. The casting compound 5 is configured to protect the components and electrical connections inside the power semiconductor module 100, in particular inside the housing 7, from certain environmental conditions and mechanical damage. The casting compound 5 may be formed by dispensing a material, for example, an uncured dielectric gel, into the housing 7, after the housing 7 has been mounted to a substrate 10 or to a base plate, and then curing the material.

The housing 7 encloses the arrangement and provides further protection from certain environmental conditions and mechanical damage. As has been described above, the housing 7 may be attached to the substrate 10 or, if the substrate 10 is arranged on a base plate, the housing 7 may be attached to the base plate, for example. In order to prevent the casting compound 5 from leaking out between the housing 7 and the substrate 10 or base plate, and to prevent contaminants or gasses (e.g., corrosive gasses) from entering the inside of the housing 7, a seal 8 may be arranged between the housing 7 and the substrate 10 (or between the housing 7 and the base plate). Referring to FIG. 2, a semiconductor module arrangement 100 comprising a seal 8 between the substrate 10 and the housing 7 is schematically illustrated.

In order to form the seal 8, the material of the seal 8 may be applied on the substrate 10 (or base plate) or to the housing 7 in a liquid or viscous form. The housing 7 may then be arranged on the substrate 10 (or base plate), with the material of the seal 8 arranged between the housing 7 and the substrate 10 (or base plate). The material of the seal 8 may then be cured, e.g., by heating the arrangement. During the curing process, the presence of contaminants may cause the formation of air bubbles and unwanted cavities in the seal 8 which may decrease the sealing abilities of the seal 8. Measurements to avoid unwanted bubble formation lead to higher costs due to additional process steps and/or longer cycle times. Furthermore, components of the viscous seal 8 can interact with other module components, especially during heating, until solidification which can have an adverse impact on the module negative, e.g., through reduced cycle times.

In addition, there is a risk that contaminants in the material forming the seal will interfere with the curing process such that non-solidified (non-cured) material remains between the housing and the cured parts of the seal 8. This may also result in reduced sealing abilities of the seal 8. For example, corrosive gasses may be able to enter the housing 7 through a non-solidified layer of sealing material.

It is therefore important to prevent air from penetrating into the material 90, so the seal 8 is free of any unwanted air bubbles or cavities. Even further, any fluids or moisture that may be present in the housing 7 should be prevented from penetrating into the seal 8. The seal 8, therefore, should also be free of any unwanted air bubbles and uncured material. Measurements to avoid unwanted bubble formation lead to higher costs due to additional process steps and/or longer cycle times.

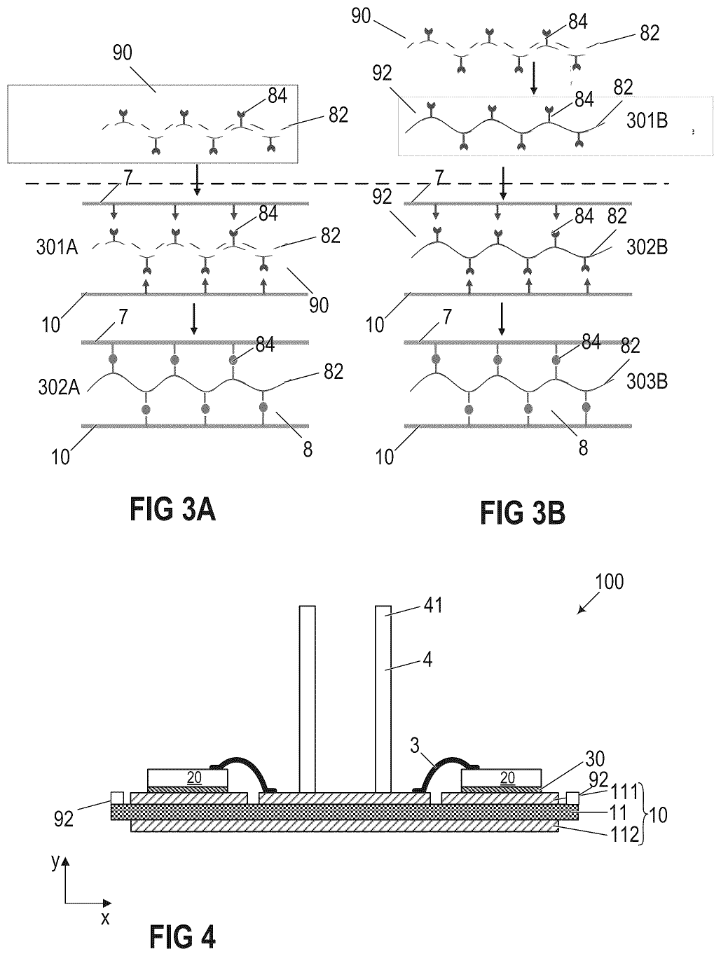

Now referring to FIG. 3A, a conventional process for forming a seal is schematically illustrated. The liquid or viscous material 90 (illustrated inside the box at the top of FIG. 3A) is dispensed on the respective surface of the substrate 10, base plate, or housing 7 (step 301A), and, once the housing 7 has been arranged on the substrate 10 or base plate, with the material 90 arranged therebetween, the material 90 is cured (step 302A). The material 90 generally comprises a matrix material 82, e.g., a silicone-based matrix material, and an adhesion promoter 84. Adhesion promoters, often also referred to as coupling agents, are chemicals that act at the interface between two different materials (e.g., an organic polymer such as the matrix material, and an inorganic material such as the housing, substrate and base plate) to enhance adhesion between the two materials. Organic and inorganic materials are very different in many ways, for example, compatibility, chemical reactivity, surface properties, and coefficient of thermal expansion, such that forming a strong adhesive bond between each of these two dissimilar materials and the matrix material 82 is difficult. An adhesion promoter 84 acts effectively at the interface between the matrix material 82 and each of the organic and inorganic materials (e.g., the interface between matrix material 82 and housing 7, and the interface between matrix material 82 and substrate 10 or base plate) to chemically and physically wed each of these dissimilar materials with the matrix material 82 via a strong cohesive bond structure.

The curing process is usually performed at temperatures that are high enough and applied for a sufficient duration to solidify (cure) the matrix material 82 and activate the adhesion promoter 84. That is, during the curing process, a crosslinking process occurs and the adhesion promoter 84 is activated, resulting in certain adhesion properties of the resulting seal 8. Once activated, the adhesion promoter is consumed, such that it becomes unreactive, i.e. it cannot be activated again at a later time.

Now referring to FIG. 3B, a method according to one example is schematically illustrated. A material 90 comprising a silicone based matrix material 82 and an adhesion promoter 84 may be provided. The material 90 may be the same or similar to the material 90 described with respect to FIG. 3A. In a first step (step 301B), the material 90 is heated to a first temperature. The first temperature, however, is lower than the temperature that is required to activate the adhesion promoter 84, or is applied for a duration that is too short (insufficient) to fully consume the adhesion promoter 84. That is, the material 90 (the matrix material 82) is cured (crosslinking process occurs) while ensuring that a sufficient amount of adhesion promoter 84 remains in the pre-seal 92 after curing. The resulting intermediate product (pre-scal 92) is solid (cured/hardened) but has limited adhesive properties, which is to say that while it might be slightly sticky, it cannot be durably attached to a surface. This makes the pre-seal 92 easy to handle. The step 301B, which is illustrated above the dashed line in FIG. 3B, may be performed at a supplier of the pre-scal 92, for example. The pre-seal 92 may then be shipped to a manufacturer of the power semiconductor module arrangement 100. A surface on which the pre-seal 92 is formed, therefore, may be a suitable working surface and the resulting pre-seal 92 may be removed from the working surface for further handling.

Different adhesion promoters 84 may usually be suitable to be used in a scal 8. Each adhesion promoter 84 may have a different specific activation time-temperature budget. In other words, heating a given adhesion promoter 84 at a given temperature for a given period of time will lead to activation and consumption of that adhesion promoter 84. On the other hand, heating that same adhesion promoter 84 at a higher temperature for a shorter time, or at a lower temperature for a longer time, can also lead to activation and consumption of that adhesion promoter 84. Many adhesion promoters 84 have an activation temperature of between 130° C. and 150° C., and activation times of between 20 minutes and 120 minutes. That is, the temperature and time during which the first step 301B is performed depends on the specific activation time-temperature budget of the adhesion promoter 84 present in the material 90. In any case, however, the first step 301B is performed for a duration and at a temperature that is lower than the activation time-temperature budget of the adhesion promoter 84 that is used for the seal 8. The matrix material 82 that is used for a silicon based seal 8, for example, generally cures at temperatures that are significantly lower than the activation temperature of the adhesion promoter 84. The curing may even occur at relatively low temperatures such as, e.g., between 50° C. and 100° C. According to one example, a curing step (step 301B) may be performed at 50° C. for 2 hours, at 60° C. for 1 hour, or at 80° C. for 30 minutes. As noted, however, the specific temperatures and durations generally depend on the specific materials and may vary.

The resulting pre-seal 92 may be shipped and may then be arranged on a surface of a substrate 10, base plate or housing 7, and the housing 7 may be arranged on the substrate 10 or base plate with the pre-seal 92 arranged therebetween (step 302B). A second heating step may follow during which the arrangement, and in particular the pre-seal 92, is heated to temperatures which correspond to or are even higher than the activation temperature of the adhesion promoter 84 (step 303B). For example, heat may be applied to the side of the substrate 10 or base plate opposite the side to which the pre-seal 92 is mounted, effecting activation of the adhesion promoter 84, and causing the resulting seal 8 to securely attach to both the housing 7 and the substrate 10 or base plate. That is, the resulting seal 8 securely attaches the housing 7 to the substrate 10 or base plate and, in addition, seals the inside of the housing 7.

Conventional non-adhesive seals such as gaskets and o-rings can also be used to seal power modules. However, such gaskets and o-rings require use of external fasteners to provide a compressive force to maintain a seal between the housing 7 and substrate 10 or base plate at all times, both before and after curing of the casting compound 5. Again, the adhesive properties of the adhesive seal 8 according to embodiments of the disclosure mean that no additional fasteners are required after the adhesion promoter is activated so as to secure the housing 7 to the substrate 10 or base plate.

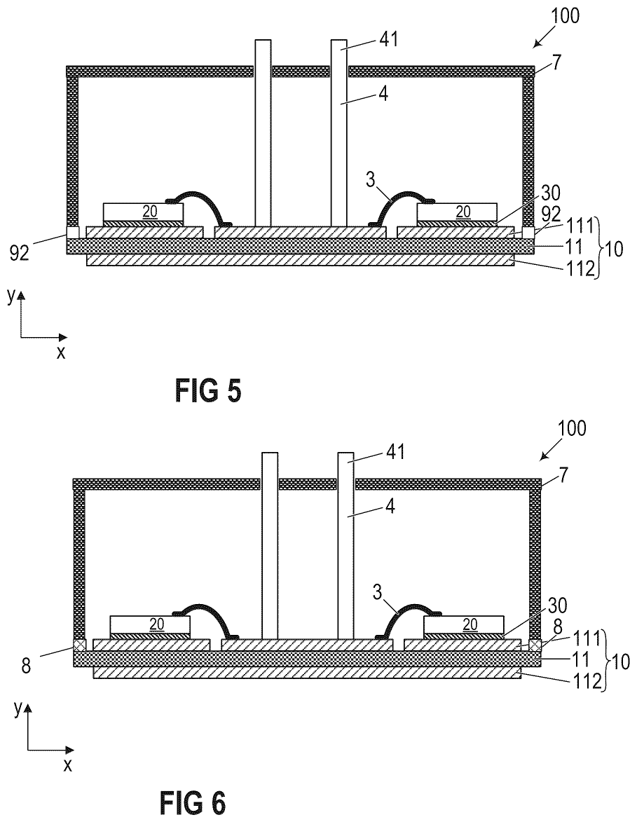

The steps 302B and 303B, as described with respect to FIG. 3B above, are again illustrated by means of FIGS. 4, 5 and 6. As is schematically illustrated in FIG. 4, a pre-produced pre-seal 92 may be arranged on a substrate 10. A housing 7 may be arranged on the substrate 10, with the pre-seal 92 arranged between the substrate 10 and the housing 7, as is illustrated in FIG. 5. A heating step may follow during which the adhesion promoter that is present in the pre-seal 92 (but which has not yet been activated) is activated, resulting in a seal 8 which has sealing properties as well as adhesion properties. That is, the resulting seal 8 has strong adhesion forces and securely attaches the housing 7 to the substrate 10.

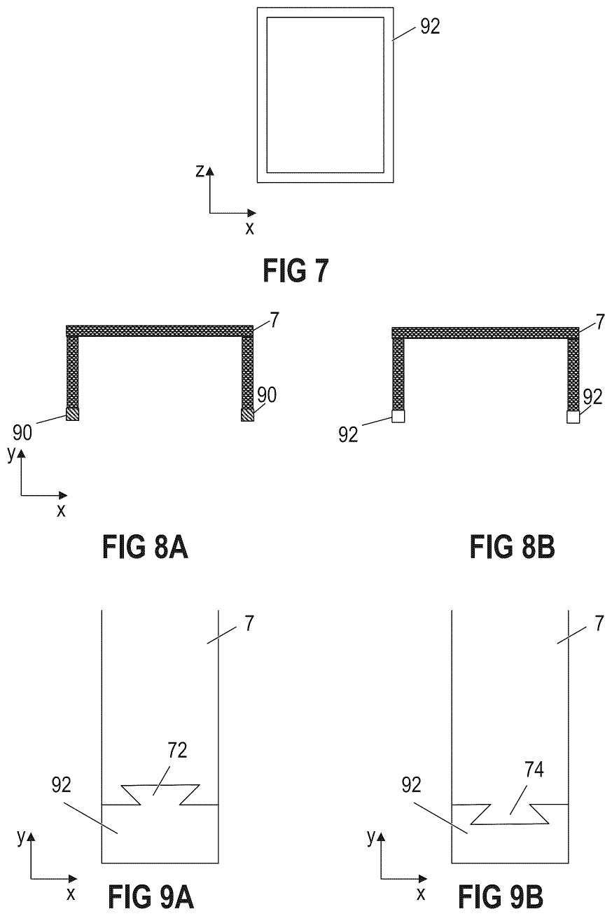

The pre-seal 92 may have any suitable form. According to one example, the pre-seal 92 forms a closed loop, as is schematically illustrated in FIG. 7, for example. The shape and size of the pre-seal 92 may depend on the shape and size of the housing 7, for example. The pre-seal 92 may have the exact same shape and dimensions as the housing 7 such that it may be arranged between the housing 7 and the substrate 10 or base plate to attach the housing 7 to the substrate 10 or base plate and seal the inside of the housing 7. Many substrates 10, base plates and housings 7 have a rectangular or square shape. Other shapes, however, are generally possible. The size of the pre-seal 92 may be slightly smaller than the size of the respective substrate 10 or base plate such that, when it is arranged on the substrate 10 or base plate, it extends along its edge. When the housing 7 is arranged on the pre-seal 92, the pre-seal 92 extends along the entire circumference of the housing 7 (i.e., along the lower surface of the sidewalls of the housing 7 that face towards the substrate 10 or base plate).

Alternatively, the pre-seal 92 may be arranged on a surface of the housing 7 first. The housing 7 with the pre-seal 92 arranged thereon may then be arranged on a substrate 10. The heating step may follow as has been described above with respect to FIG. 6 to form the final seal 8. If the substrate 10 is arranged on a base plate, the housing 7 may be arranged on the base plate, with the pre-seal 92 arranged between the base plate and the housing 7.

It is possible to manufacture and ship the pre-seal 92 independently. According to another example, however, it is also possible to form the pre-seal 92 on the housing 7 and ship the housing 7 together with the pre-seal 92 formed thereon. This is schematically illustrated in FIGS. 8A and 8B. In a first step, the material 90 including the (silicone based) matrix material and the adhesion promoter may be applied to the housing 7 (e.g., on a lower surface of the sidewalls of the housing 7 that face towards the substrate 10 or base plate when the housing 7 is arranged on the substrate 10 or base plate). This is schematically illustrated in FIG. 8A. A heating step is performed to cure the matrix material without activating or without fully consuming the adhesion promoter, thereby forming the pre-seal 92 (FIG. 8B). The housing 7 with the pre-seal 92 formed thereon may then be arranged on a substrate 10 or base plate and the final seal 8 may be formed by performing the second heating step as has been described above.

The lower surface of the sidewalls of the housing 7 may be a flat or essentially flat surface, as is schematically illustrated in FIGS. 8A and 8B, for example. In this case, the pre-seal 92 is required to have certain adhesive properties in order to remain attached to the flat lower surface. It is, however, also possible that the lower surface of the sidewalls is formed to have at least one recess or undercut 72, for example. This is schematically illustrated in FIG. 9A. When the material 90 is applied to the lower surface of the housing 7, the material 90 fills the recess 72 formed in the sidewall of the housing 7, and further forms a layer of material 90 that extends from the lower surface in a vertical direction y. Once the material 90 has been cured and the pre-seal 92 is solid, it is securely attached to the lower surface of the housing 7 without having any adhesive properties yet, or having only limited adhesive properties. The specific form of the recess 72 illustrated in FIG. 9A is merely an example. A recess or undercut 72 may generally have any suitable form. In this case, the pre-seal 92 remains attached to the sidewall of the housing without having any adhesive properties.

A similar effect may be achieved if the lower surface of the housing 7 comprises a protrusion 74, and the material 90 is applied to the lower surface of the housing 7 such that it forms a layer of material 90 that extends from the lower surface in a vertical direction y and entirely encloses the protrusion 74, as is exemplarily illustrated in FIG. 9B. The recess 72 or protrusion 74 may be a continuous recess 72 or protrusion 74 along the entire circumference of the housing 7. It is, however, also possible, that a plurality of recesses 72 and/or protrusions 74 is arranged along the circumference of the housing 7.

When forming a pre-seal 92 (either independently or on a lower surface of the housing, for example), the curing step at a temperature below the activation temperature of the adhesion promoter 84 may be carried out in a vacuum chamber, for example. This prevents air from penetrating into the material 90. The resulting pre-seal 92 as well as the final seal 8, therefore, are free of any unwanted air bubbles or cavities. Even further, any fluids or moisture that may be present in the housing 7 may be prevented from penetrating into the material 90. The resulting pre-seal 92 as well as the final seal 8, therefore, are also free of any unwanted fluids.

According to another example, a housing 7 with a pre-attached pre-seal 92 may be formed in a two-shot (2K) injection molding process, for example. Techniques that are known as 2K injection molding allow to form injection-molded parts comprising two different materials in the same mold. A first material (e.g., the material forming the housing 7) may be filled into a mold by means of at least one injection. At least one second injection is used to fill a second material (e.g., the material 90 forming the pre-seal 92) into a mold containing the housing 7, where the mold has defined locations adjacent the housing 7. The two materials, in this way, may be connected to each other. It is important that during the second step of the 2K processes, e.g., during formation of the pre-seal 92, that the temperature be held sufficiently high and for a sufficient time to allow curing of the second material 90 but at a low enough temperature and/or for a time that is short enough to prevent the adhesion promoter from being fully consumed during the curing process. The 2K injection molding process can be a manual two-step process, or a fully automated process using a rotary injection molding form, for example. The two materials may be filled into the mold in any suitable order, as long as the temperature can be held low enough or for an amount of time insufficient to allow full consumption of the adhesion promoter in the pre-seal material 90.

According to this example, the housing/pre-seal assembly 7, 92 may be mounted to a substrate 10 by placing it on the substrate 10 with the pre-seal 92 arranged between the housing 7 and the substrate 10 and by pressing the housing 7 toward the substrate. The pre-seal 92 is then heated in order to activate the adhesion promoter remaining in the pre-seal material 90, for example, by heating the other side of the substrate 10. Pressure may be removed from the housing 7 and the heat may be removed once the adhesion promoter is fully activated and the pre-seal 92 seal is fully adhered to the substrate 10.

It is generally also possible to form a pre-seal 92 on a substrate 10 or base plate, similar to what has been described with respect to the housing 7 above. A housing 7 may then be arranged on the substrate 10 or base plate with the pre-seal 92 arranged between the housing 7 and the substrate 10 or base plate. The final seal 8 may be formed by performing the second heating step as has been described above.

As used herein, the terms “having”, “containing”, “including”, “comprising” and the like are open ended terms that indicate the presence of stated elements or features, but do not preclude additional elements or features. The articles “a”, “an” and “the” are intended to include the plural as well as the singular, unless the context clearly indicates otherwise.

The expression “and/or” should be interpreted to cover all possible conjunctive and disjunctive combinations, unless expressly noted otherwise. For example, the expression “A and/or B” should be interpreted to mean only A, only B, or both A and B. The expression “at least one of” should be interpreted in the same manner as “and/or”, unless expressly noted otherwise. For example, the expression “at least one of A and B” should be interpreted to mean only A, only B, or both A and B.

It is to be understood that the features of the various embodiments described herein can be combined with each other, unless specifically noted otherwise.

Although specific embodiments have been illustrated and described herein, it will be appreciated by those of ordinary skill in the art that a variety of alternate and/or equivalent implementations can be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A method, comprising:
applying a first material to a first surface, the first material comprising a matrix material and an adhesion promoter, wherein the matrix material is configured to cure when heated to a defined temperature for a defined period of time, and wherein the adhesion promoter is configured to be activated when heated to a temperature that is higher than the defined temperature and/or for a period of time that is longer than the defined period of time; and
heating the first material to the defined temperature for the defined period of time such that the matrix material cures and the adhesion promoter remains inactive, thereby forming a pre-seal.

2. The method of claim 1, further comprising:
removing the pre-seal from the first surface;
arranging the pre-seal between a housing and a substrate or a base plate of a power semiconductor module; and
heating the pre-seal to a temperature that is equal to the defined temperature for a period of time that is longer than the defined period of time, or to a temperature that is greater than the defined temperature for a period of time that equals or is longer than the defined period of time, thereby activating the adhesion promoter and forming a seal between the housing and the substrate or the base plate, the seal forming an adhesive bond with the housing and with the substrate or the base plate.

3. The method of claim 2, wherein the pre-seal is arranged between the housing and the substrate or the base plate such that the pre-seal extends along an entire circumference of the housing along a lower surface of sidewalls of the housing that face towards the substrate or the base plate.

4. The method of claim 1, wherein the first surface is a surface of a housing, the method further comprising:
arranging the housing with the pre-seal arranged thereon on a substrate or a base plate; and
heating the pre-seal to a temperature that is equal to the defined temperature for a period of time that is longer than the defined period of time, or to a temperature that is greater than the defined temperature for a period of time that equals or is longer than the defined period of time, thereby activating the adhesion promoter and forming a seal between the housing and the substrate or the base plate, the seal forming an adhesive bond with the housing and with the substrate or the base plate.

5. The method of claim 4, further comprising:
filling a material different from the first material into a mold to form the housing,
wherein applying the first material to the first surface comprises subsequently filling the first material into the mold.

6. The method of claim 4, wherein the surface of the housing comprises at least one recess, and wherein the first material is applied to the surface such that the first material fills the at least one recess and forms a layer of material that extends from the surface in a vertical direction.

7. The method of claim 4, wherein the surface of the housing comprises at least one protrusion, and wherein the first material is applied to the surface such that the first material forms a layer of material that extends from the surface in a vertical direction and entirely encloses the at least one protrusion.

8. The method of claim 4, wherein the pre-seal is arranged between the housing and the substrate or the base plate such that the pre-seal extends along an entire circumference of the housing along a lower surface of sidewalls of the housing that face towards the substrate or the base plate.

9. The method of claim 1, wherein the first surface is a surface of a substrate or a base plate, the method further comprising:
arranging a housing on the substrate or a base plate such that the pre-seal is arranged between the housing and the substrate or the base plate; and
heating the pre-seal to a temperature that is equal to the defined temperature for a period of time that is longer than the defined period of time, or to a temperature that is greater than the defined temperature for a period of time that equals or is longer than the defined period of time, thereby activating the adhesion promoter and forming a seal between the housing and the substrate or the base plate, the seal forming an adhesive bond with the housing and with the substrate or the base plate.

10. The method of claim 9, wherein the pre-seal is arranged between the housing and the substrate or the base plate such that the pre-seal extends along an entire circumference of the housing along a lower surface of sidewalls of the housing that face towards the substrate or the base plate.

11. The method of claim 1, wherein the matrix material is a silicone based matrix material.

12. The method of claim 1, wherein the defined temperature is between 50° C. and 100° C., and wherein heating the pre-seal to a temperature that is greater than the defined temperature comprises heating the pre-seal to a temperature of between 130° C. and 150° C.

13. The method of claim 1, wherein the pre-seal forms a closed loop.

14. A housing for a power semiconductor module arrangement, the housing comprising:
sidewalls;
a cover; and
a pre-seal arranged on a lower surface of the sidewalls, wherein the pre-seal comprises a cured matrix material and an uncured adhesion promoter.

15. The housing of claim 14, wherein the lower surface comprises at least one recess, and wherein the pre-seal fills the at least one recess and forms a layer that extends from the lower surface in a vertical direction.

16. The housing of claim 14, wherein the surface comprises at least one protrusion, and wherein the pre-seal forms a layer that extends from the lower surface in a vertical direction and entirely encloses the at least one protrusion.
